(19) United States
(12) Patent Application Publication
(10) Pub. No.: US 2013/0122301 A1
(43) Pub. Date: May 16, 2013

(54) PRESSURE SENSITIVE MICROPARTICLES FOR MEASURING CHARACTERISTICS OF FLUID FLOW

(71) Applicant: University of Utah Research Foundation, Salt Lake City, UT (US)

(72) Inventor: Carlos H. Mastrangelo, Salt Lake City, UT (US)

(73) Assignee: University of Utah Research Foundation, Salt Lake City, UT (US)

(21) Appl. No.: 13/725,360

(22) Filed: Dec. 21, 2012

Related U.S. Application Data
(63) Continuation of application No. PCT/US11/41859, filed on Jun. 24, 2011.
(60) Provisional application No. 61/358,236, filed on Jun. 24, 2010.

(51) Int. Cl. G01F 1/74; G01N 21/55; C23C 16/01

(52) U.S. Cl. CPC G01F 1/74; C23C 16/01; G01N 21/55
USPC 428/402; 216/56; 356/442; 252/408.1

(57) ABSTRACT

Microparticles (200) and systems and methods for measuring characteristics of fluid flow using the microparticles are described. The microparticle (200) can include at least one flexible wall (205) which can deflect when an outer pressure on an outer side of the wall is different than an inner pressure on an inner side of the wall. The microparticle (200) can also include a void (215) enclosed by the at least one wall (205) and can change shape as the wall (205) deflects.

### RELATED APPLICATIONS

This application claims the benefit of International PCT Application No. PCT/US11/41859, filed Jun. 24, 2011 which claims the benefit of U.S. Provisional Patent Application Ser. No. 61/358,236, filed on Jun. 24, 2010, which are each hereby incorporated herein by reference in their entireties.

### BACKGROUND

Flow visualization is the process of making the physics of fluid flows (gases and liquids) visible. Flow field mapping is useful in improving understanding and characterizing of flows in many engineering fields in the biomedical, chemical, oil and aerospace industries. Flow field mapping can also fulfill a role in the design and experimental test of naval and aircraft surfaces. In particular, quantitative flow visualization aims to develop methodologies that map velocity and pressure fields in a flow.

Some flow visualization techniques have involved single-point fluid flow velocity measurement techniques such as hot wire anemometry, laser doppler anemometry, and pitot tubes to find velocity at a specific point. However, with these techniques flow analysis can be difficult because flow structures can be difficult to clearly identify. Obtaining an overview of the flow is difficult due to the difficulty in data interpretation.

Some solutions have attempted to make single point measurements at many different points in the flow field. However difficulties can arise in this form of data analysis. For example, due to cost of laser doppler anemometry, point measurements cannot generally be acquired at more than a few points. This lends to interpretive analysis of the data which can engender error. Further, many single point measuring techniques alter the flow that is being measured.

Fluid flow pressure field measurement is generally performed differently than fluid flow velocity measurements. Whereas PIV is useful for measuring flow velocities in a three dimensional domain, equivalent techniques for recording pressure fields in real time in a three dimensional domain have not been developed. A common technique used for measuring fluid flow pressure fields uses scanning pressure probes. These probes can contain a calibrated pressure transducer at a tip of the probe which can measure pressure at the probe tip. Pressure fields can also be measured on solid surfaces using pressure sensitive paints.

One of the most widely used methods of quantitative flow velocity visualization is particle image velocimetry or PIV. PIV is an optical method of fluid visualization. The fluid is seeded with tracer particles which are generally assumed to faithfully follow the flow dynamics. The motion of these seeding particles is used to calculate velocity information of the flow being studied. A typical PIV apparatus 100 such as that shown in FIG. 1 consists of a camera 150, a high power light source 110, for example a laser, an optical setup 115, 145 to convert the laser output light to a thin light sheet 125 and for focusing an image at the camera, an optional mirror 120, seeding particles 135, and fluid within a channel 130 and having a fluid flow 140. Other techniques used to measure flows are laser doppler velocimetry and hot-wire anemometry. PIV produces two dimensional vector fields, while the other techniques measure the velocity at a point, and thus are much slower than PIV.

Pressure fields are measured differently than velocity fields. Unlike PIV, there is no equivalent technique that permits recording of pressure fields in real time in a two dimensional domain. A common mapping technique uses pressure probes. These probes contain a calibrated pressure transducer at its tip. It is intrinsically assumed that the probe is small hence minimizes disruptions to the pressure and flow fields. Because this is a single point measurement technique mapping an entire field requires mechanical scanning of the probe.

Pressure fields can also be measured on solid surfaces using pressure sensitive paints. Pressure-sensitive paint (PSP) is a relatively new measurement technique for surface pressure measurements in aerodynamic testing. The fundamental operating principle of PSP is oxygen quenching of luminescence the paint. Light intensity emitted by the paint is measured by a photodetector, and is inversely proportional to the local air pressure.

Conventional paint formulations were first applied to wind tunnel testing in the late 1980s and early 1990s, with initial tests demonstrating that PSP could successfully resolve the chordwise pressure distribution on a wind tunnel model. The primary advantage of PSP over traditional, point-measurement techniques is high spatial resolution. PSP can provide a global map of surface pressure with a spatial resolution primarily limited by the pixel resolution of the imaging device. Comprehensive reviews of PSP have been written by Liu et al. Pressure sensitive paint (PSP) is based on the principle that the concentration of oxygen inside certain polymer films reflects the oxygen pressure over the film. The oxygen concentration inside the film acts to quench the triplet emission of luminophores dissolved in the film, and this quenching is the basis for the use of PSP in wind tunnel research. The luminescence intensity of the film thus can be used to map the pressure on various parts of an airfoil.

Unfortunately, PSP is not without its undesirable characteristics. One of these characteristics is that the response of the luminescent molecules in the PSP coating degrades with time of exposure to the excitation illumination. This degradation occurs because of a photochemical reaction that occurs when the molecules are excited. Eventually, this degradation of the molecules determines the useful life of the PSP coating. This characteristic becomes more important for larger models, as the cost and time of PSP reapplication becomes a significant factor. A second undesirable characteristic of PSP is that the emission intensity is affected by the local temperature. This behavior is due to the effect temperature has on the energy state of the luminescent molecules, and the oxygen permeability of the binder. This temperature dependence becomes even more significant in compressible flow tests, where the recovery temperature over the model surface is not uniform. Thus for accurate measurement of pressure it is also necessary to measure the temperature, which may vary over the airfoil and over time. The simplest way to do this is to incorporate two luminophores that give spectrally resolved measurement of oxygen pressure and of temperature.

Finding two compatible luminophores, one of which is pressure dependent and the other temperature dependent, has proven difficult. This is because the most of the common luminophores potentially useful for PSP generally have regions of emission overlap that makes clean separation of their emissions impossible. It is also necessary that the two luminophores do not interact when incorporated into a single film. A significant drawback of the PSP film approach is that it does not permit the measurement of pressure within the flow field.

Recently the pressure sensitive paint technique has been used to either coat or bind luminophores on microparticles (0.5-3 μm diameter). Others have demonstrated that air-born microspheres loaded with pressure-sensitive dyes could be used to simultaneously acquire the images of both velocity and pressure fields because these particles were sufficiently small to accurately follow the fluid flow and showed the potential for monitoring a two-dimensional pressure field.

In spite of these proof-of-concept demonstrations, the reliability of these optical sensing techniques still needs to be improved before they can find use in practical applications. For instance, it has been shown that the detected luminescent signal was strongly dependent on experimental parameters that include the temperature, the light source, the schemes for both illumination and detection, the index of refraction of the medium, and the concentration of dye. These problems can, in principle, be solved by incorporating two different reference and the other for sensing oxygen. In an ideal system, the luminescent dyes should be selected such that both of them have similar response to the experimental parameters (e.g., temperature) while the reference dye will not be quenched by oxygen and the sensing dye will strongly respond to the change of oxygen concentration.

In both the film and microsphere implementations, aside from the temperature dependence and eventual photobleaching, a major flaw is that the translation of the signal observed into pressure is dependent on the illumination. This is particularly problematic in a three dimensional environment. Furthermore the photobleaching is also a function of the illumination intensity that complicates the stability of the signal readout even more. In addition, the nature of the luminophore approach has limited the utilization of these particles to low pressure gaseous environments. In many technologically relevant areas such as the development of biomedical microdevices, the pressure must be monitored in a liquid, typically aqueous environment.

### SUMMARY

A microparticle for use in measuring characteristics of fluid flow can include at least one flexible wall which can deflect when an outer pressure on an outer side of the wall is different than an inner pressure on an inner side of the wall. The microparticle can also include a void enclosed by the at least one wall and can change shape as the wall deflects. In one aspect, the microparticle has a largest dimension less than about 10 μm. The flexible wall can be a substantially impermeable wall sufficient to avoid equalization of pressure across the wall. The microparticle can have a substantially spherical shape or any other various suitable shapes (e.g. disc, box, etc). Although not required in all embodiments, the flexible wall can have a plurality of layers of a common material. A first layer of the plurality of layers can be a thin holey layer and a second layer of the plurality of layers can be thicker than the first layer and can cover holes in the first layer. The flexible wall can be a plurality of flexible walls structured such that the void is substantially rectangularly shaped. The flexible wall can have a reflective surface configured to reflect incident light. The flexible wall can be made from polysilicon although other materials can be suitable. In one specific example, the flexible wall can have a thickness of about 0.25 μm. In another specific example, the microparticle can have a diameter less than 2 μm.

In accordance with a more detailed aspect, a system is provided for measuring characteristics of fluid flow using microparticles as described above. The system can include a fluid configured to flow in a defined space. A light source can illuminate the pressure sensitive microparticle when the pressure sensitive microparticle is disposed in the fluid. The light source can emit light at one or more predetermined incident wavelengths. A detector can be configured to detect a reflected wavelength of light reflected from the pressure sensitive microparticle. A pressure analyzer can be used to compare the incident wavelength with the reflected wavelength to determine an amount of deflection of the wall of the pressure sensitive microparticle, and to calculate a fluid pressure of the fluid based on the amount of deflection of the wall. In some aspects, the light source can be a scanning light source configured to scan across the fluid to illuminate the fluid at a plurality of positions. The system can include a flow analyzer configured to detect fluid flow characteristics based on a plurality of flow positions of the pressure sensitive microparticle within the fluid as detected by the detector.

In accordance with another aspect of the present invention, a method is described for measuring pressure using a pressure sensitive microparticle, such as the microparticles described above. At least one pressure sensitive microparticle can be inserted into a fluid flow. Any number of microparticles can be inserted. For example, 1,000, or 1,000,000, or 1,000,000,000 microparticles can be inserted into the fluid flow depending on the resolution desired and the fluid flow volume. The microparticle can have a flexible wall which deflects as a function of pressure across the wall. The wall can be deflected by pressure from fluid in the fluid flow. A beam of light can be reflected from the wall of the microparticle. In one aspect, this can include directing an incident light beam toward the microparticle. The beam of light can be detected and an output based on a wavelength shift of the reflected beam of light from a pre-reflection wavelength can be measured. In detecting the beam of light, the method can include capturing images of the microparticle(s) using a camera. The wavelength shift determined from the detected beam of light can then be correlated with a fluid pressure. The method can include detecting fluid flow characteristics based on a plurality of flow positions of the microparticle within the fluid as detected by a detector. In some cases, the method can include compensating the output for spurious reflections in the fluid from surfaces other than the flexible wall of the microparticle. This correlation can be extended across the plurality of microparticles injected into the fluid.

In accordance with one aspect, a method is described for creating pressure sensitive microparticles for measuring fluid flow characteristics. A sacrificial spacer can be provided and a thin membrane can be formed around the sacrificial spacer. The membrane can include pores. The sacrificial spacer can be removed from within the thin membrane through the pores to form a void within the thin membrane. A sealing membrane can be deposited around the thin membrane in a low-pressure environment to seal the void by sealing the pores and to create a predetermined internal pressure within the void. In one aspect, the thin membrane can be formed using a substantially non-diffusive material. In another aspect, forming the thin membrane and depositing the sealing membrane can be performed using a submicron lithography patterning technique. The method can include forming the thin membrane using an at least partially diffusive material and forming a barrier between the void and the sealing membrane to prevent diffusion of gas between the void and an area outside of the sealing membrane. Also, the thin membrane and the sealing membrane can be formed such that a largest dimension of the pressure sensitive microparticle is less than about 10 μm. However, other dimensions can also be suitable for particular applications.

### BRIEF DESCRIPTION OF THE DRAWINGS

FIG. 1 is a perspective and partially cross-sectional view of a system for quantitative flow velocity visualization in accordance with an embodiment of the present invention;

FIG. 2a is a perspective view of a microparticle in accordance with an embodiment of the present invention;

FIG. 2b is a cross sectional view of the microparticle of FIG. 2a with substantially equal pressure inside and outside of the microparticle;

FIG. 2c is a cross sectional view of the microparticle of FIG. 2a with a greater pressure on the outside of the microparticle than on the inside of the microparticle;

FIG. 3 is a graph illustrating the reflectivity of Fabry-Perot pressure sensing particles versus wavelength for two different gaps in accordance with an embodiment of the present invention;

FIG. 4 is a graph of the reflectivity of Fabry-Perot elaton versus wavelength for different gaps, including wavelength-dependent material properties, in accordance with an embodiment of the present invention;

FIGS. 5a-5f are cross-sectional side views illustrating microparticle formation in accordance with an embodiment of the present invention;

FIG. 6a is a scanning electron microscope (SEM) image of microparticles before release into a fluid flow, in accordance with an embodiment of the present invention;

FIG. 6b is a photograph of microparticles at atmospheric pressure, in accordance with an embodiment of the present invention;

FIGS. 7a-7b are photographs of 10 μm diameter microparticles in a water suspension in accordance with an embodiment of the present invention;

FIGS. 8a-d illustrate particles constructed on top of pitted surfaces to form quasi-retroreflective spectroscopic particles in accordance with embodiments of the present invention, wherein FIG. 8a is a perspective line drawing of a retroreflective particle, FIG. 8b is a cross-sectional side view of the particle of FIG. 8a, FIG. 8c is a SEM image of a top view of a retroreflective particle, and FIG. 8d is a photograph of a side view of a retroreflective particle;

FIG. 9a-c illustrates a comparison of spectral reflectivity of coated spherical microparticles numerically calculated using Mie Theory and a Slab Model;

FIG. 9d-k illustrate a method for forming spherical particles in accordance with one embodiment of the present invention;

FIG. 10 is a flow diagram of a method for fabricating pressure sensing microparticles in accordance with embodiments of the present invention using a permeable film approach;

FIG. 11 is a schematic of a high speed spectral imaging instrument for spectroscopic particle-based pressure measurement in microchannel flows in accordance with embodiments of the present invention;

FIG. 12 is a scanning electron microscope image of microparticles before release into a fluid flow, illustrating normal and ruptured microparticle shells in accordance with an embodiment of the present invention;

FIG. 13 is an optical photograph of released 14 μm-diameter spectroscopic slab-type particles in a water suspension and a graph illustrating measured microparticle reflectivity at normal incidence in air at atmospheric conditions in accordance with embodiments of the present invention;

FIG. 14 includes graphs of measured particle reflectivity versus pressure inside a liquid (H₂0) chamber, and of wavelength shift versus chamber pressure for two different reflectivity dips in accordance with embodiments of the present invention;

FIG. 15 illustrates an example setup used for measurement of internal pressure within a microfluidic chip and a graph of microparticle measured pressure versus distance from chip inlet in accordance with embodiments of the present invention;

FIGS. 16a-g are stages of a manufacturing process for inserting pressure sensitive microparticles within a wall in accordance with an embodiment of the present invention;

FIGS. 17a-b are photographs of an example PDMS chip with embedded particles inside the lower channel wall at random locations along a long serpentine channel in accordance with an embodiment of the present invention;

FIG. 18a shows the spectral characteristics of four different microparticles at different locations observed from the glass side under a flow of 3.5 cm/s displaying different spectra shift corresponding to the pressure at their respective locations in accordance with an embodiment of the present invention;

FIG. 18b shows the conversion of the shift into pressure versus particle location from the inlet. The measurements indicate an approximate linear pressure drop vs. distance in accordance with an embodiment of the present invention;

FIG. 19 shows the observed particle color changes versus external pressure for a single particle in accordance with an embodiment of the present invention; and

FIG. 20 shows an optical photograph of three released 0.7 μm-gap, 14 μm-diameter slab microparticles in water suspension, and the corresponding optical reflectance at atmospheric pressure measured using an Ocean Optics spectrometer attached to a microscope in accordance with embodiments of the present invention.

### DETAILED DESCRIPTION

Reference will now be made to the exemplary embodiments illustrated, and specific language will be used herein to describe the same. It will nevertheless be understood that no limitation of the scope of the invention is thereby intended. Additional features and advantages of the invention will be apparent from the detailed description which follows, taken in conjunction with the accompanying drawings, which together illustrate, by way of example, features of the invention.

As used herein, the terms “light” and “electromagnetic radiation” can be used interchangeably and refer to light or electromagnetic radiation in the ultraviolet, visible, near infrared, and infrared spectra. The terms can further more broadly include electromagnetic radiation such as radio waves, microwaves, x-rays, and gamma rays. Thus, the term “light” is not limited to electromagnetic radiation in the visible spectrum.

As used herein, a “substrate” can refer to any of a variety of materials, layers, etc. For example, in terms of a semiconductor, the “substrate” may refer to a silicon wafer, or may refer to any of a variety of dielectric, conductive, or other layers in the semiconductor. For purposes of this disclosure, the substrate can generically refer to a layer or material capable of supporting another layer or material thereon.

It is noted that, as used in this specification and the appended claims, the singular forms “a,” “an,” and “the” include plural referents unless the context clearly dictates otherwise. Thus, for example, reference to “a particle” includes one or more of such devices, reference to “a layer” includes reference to one or more of such members, and reference to “depositing” includes reference to one or more of such steps.

As used herein, the terms “about” and “approximately” are used to provide flexibility, such as to indicate, for example, that a given value in a numerical range endpoint may be “a little above” or “a little below” the endpoint.

As used herein, the term “substantially” refers to the complete or nearly complete extent or degree of an action, characteristic, property, state, structure, item, or result. The exact allowable degree of deviation from absolute completeness may in some cases depend on the specific context. However, the nearness of completion will generally be so as to have the same overall result as if absolute and total completion were obtained. The use of “substantially” is equally applicable when used in a negative connotation to refer to the complete or near complete lack of an action, characteristic, property, state, structure, item, or result.

As used herein, a plurality of components may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 2, 3, 4, and 5, individually.

Described herein are microparticles, systems and methods for the measurement of pressure fields in flows. The measurements can be made based on the use of minute particle-based sensors. During a measurement, a plurality of these particles can be incorporated in the flow to produce an image map of the pressure field over the entire domain. Each pressure-sensitive particle can consist of a Fabry-Perot resonator of micrometer or smaller dimensions that can be interrogated optically at high speed using an incident illumination source such as a white light, a laser, etc. The spectrum, or color, of the light reflected off the particle is a function of pressure. Reflected light signals can then be correlated to pressure fields and velocity profiles throughout the fluid flow. Furthermore, the pressure sensitive particles can be constructed using batch micromachining techniques.

This new family of pressure-sensitive particles, which is described in more detail below, can eliminate practical problems associated with previous attempts at measurement of pressure fields in fluids. The pressure sensitive particles herein are not based on the use of chemically sensitive luminophores but physical, pressure sensitive optical microresonators. Each engineered pressure-sensing microparticle includes a semi-transparent shell enclosing a cavity having an internal pressure less than external fluid pressure. The cavity also has a characteristic optical resonance. The thickness of the shell is designed such that dimensions of the cavity are dependent on the external absolute pressure. The optical resonance, and the corresponding pressure, can hence be interrogated optically. In essence, each microparticle behaves as a Fabry-Perot pressure sensor embedded in the flow. In this scheme, white light is used for illumination and the spectrum of the particle reflected light is examined. However, any other wavelength of light can be used which exhibits pressure dependency. The pressure readout signal is represented as a wavelength shift of the optical resonance spectrum; thus the readout is completely independent of variations in illumination intensity levels (for the same illumination spectra). Furthermore, the sensitivity of the particle spectral resonance characteristics is much smaller than the sensitivity to pressure; hence temperature dependence concerns are minimized. These new particles can open up new more robust applications for particle based imaging manometry in a wide range of engineering fields. In particular the particle can find utility in microfluidic chip environments. The construction of several types of optical resonators that reduce or eliminate angular dependences of the device reflectivity is also provided.

A pressure field measurement technique can combine the benefits of PIV and the accuracy of scanning probe methods. The construction of pressure-sensitive engineered particles and a measurement instrument to implement a Particle Imaging Manometry (PIM) system are also outlined. A family of pressure sensitive microparticles can be provided. These particles are engineered optical cavity microresonators. Each particle includes a semi-transparent compliant shell enclosing a vacuum sealed cavity. The cavity dimensions and the corresponding resonant spectra are dependent on the absolute pressure present outside the cavity. The characteristic pressure-dependent optical resonance can be directly observed in the spectrum of the particle reflectivity. This approach is attractive because the sensor signal is largely independent of illumination level, temperature and fluid phase (gas or liquid). Several types of pressure-sensing particles can be suitable for different applications. The design and construction of (a) simple slab-type spectroscopic particles, (b) high-reflectivity particles with built-in retro-reflectors that abate angular dependencies, and (c) spherical iso-reflective spectroscopic pressure-sensing particles are disclosed.

Microfabrication methods for the high volume production of the spectroscopic particles are also described. Fabrication methods are described for three types of geometries and can be extended using the principles to other shapes in a similar manner. A variant of the same technique can be used to construct particles with built-in retroreflectors and a lithography-free technique can be used for the fabrication of spectroscopic spherical particles. The construction of these particles poses interesting and exciting micro fabrication challenges that ultimately lead to the utilization of sub-micron patterning techniques for ultra-high volume production of these particles.

A high speed optical instrument can be provided that is capable of reading out the optical spectrum of the reflected light from an assemble spectroscopic particles at very high speeds on a two dimensional field. As one test platform an instrument can be specifically designed for micro-PIM applications. Such instrument provides the measurement of spectroscopic images in millisecond. In our basic approach a series of high-speed lasers or narrow-filtered LEDs can be used to produce a series of high-speed single-wavelength photographs of the same field to determine the spectrum of each particle in a very short time.

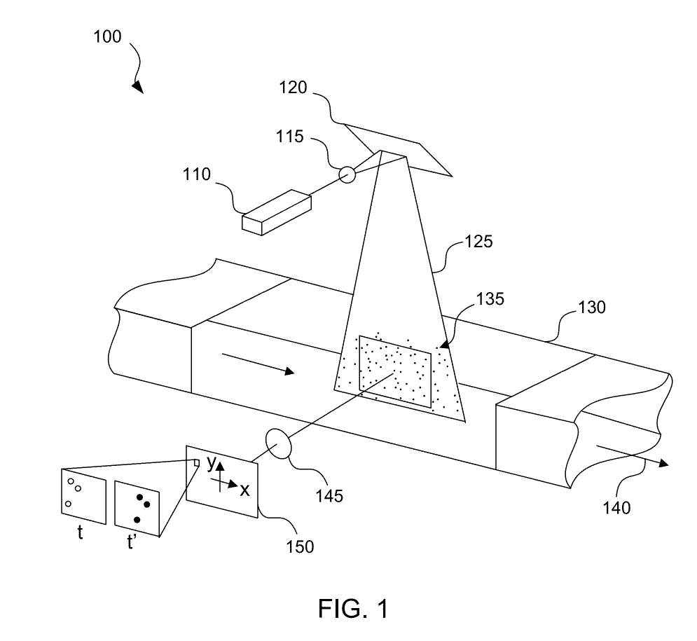

A system 100 can be deployed using a setup such as the one illustrated in FIG. 1 and using microparticles 135 and a scanning system as described herein. The techniques herein used to measure pressure fields can be referred to as Particle-based Imaging Manometry or PIM. The PIM technique is based on the utilization of pressure sensitive particles. Each of these particles consists of a microfabricated pressure transducer of micron-sized dimension so small that it can be embedded in the flow 140 without substantially altering flow characteristics. The microfabricated particle can be interrogated optically in the same manner as conventional PIV. Hence, the velocity field is readily determined from the particle motion, shown as times t and t′, but in addition the spectrum of the light reflected off the particle is also a function of pressure.

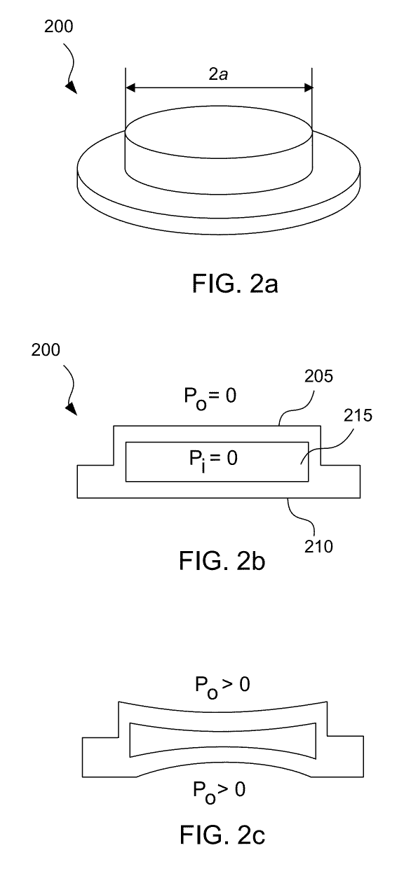

Reference will now be made to FIGS. 2a-2c. Each pressure sensing particle 200 can consist of a hollow pill-like cavity 215 (as shown in FIG. 2b) of micrometer dimensions. The particle can be formed from a semi-transparent elastic shell enclosing a reference cavity. The reference cavity may be under vacuum but can merely have pressure which is lower than an external pressure encountered in a fluid flow. The thickness of the shell is designed such that the cavity gap and corresponding optical frequency is dependent on the external absolute pressure.

The particle 200 and/or the cavity 215 may comprise any suitable shape such as rectangular, square, circular, oval, etc. The cavity is bounded by thin diaphragm walls 205, 210 spaced by gap as shown in FIG. 2b. The interior of the cavity is hermetically sealed at very low pressure hence acting as a vacuum reference. If the external pressure Pₒ of the particle is larger than the reference cavity pressure the diaphragms deflect thus changing their separation gap as in FIG. 2c. This gap can be measured optically. The device diaphragms form a Fabry-Perot resonator or etalon of characteristic gap g(ΔP). In a simple Fabry-Perot resonator and at normal incidence the optical reflectance as a function of wavelength λ is

$$R ( λ ) = \frac{1}{1 + \frac{{T}_{d}^{2}}{4 {R}_{d}} \cdot {csc}^{2} ( \frac{2 π g}{λ} )} \qquad ( 1 )$$

Where T_{d} and R_{d}, are the diaphragm transmission and reflection coefficients, and g(P) is the pressure dependent gap. The reflectance is zero when the argument of the csc( ) is 2π, hence λₘᵢₙ=g(ΔP). The minimum reflectance wavelength shift is related to the external pressure change.

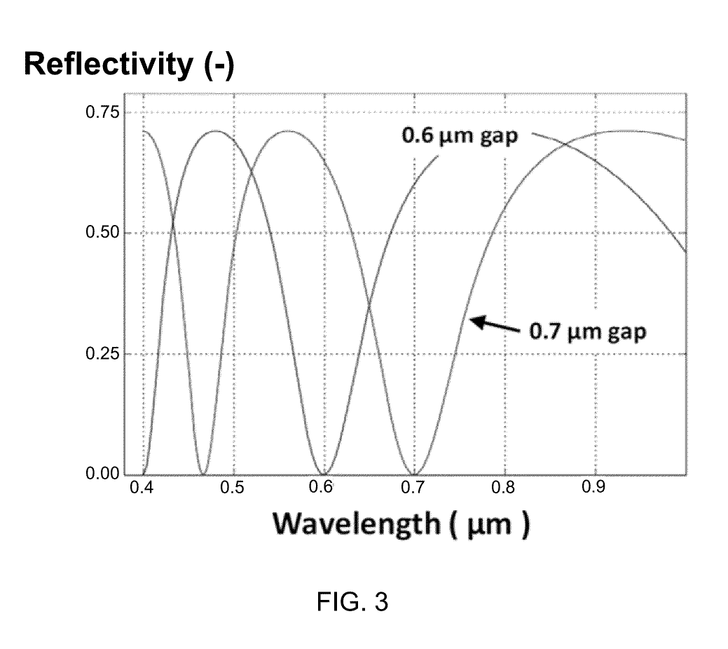

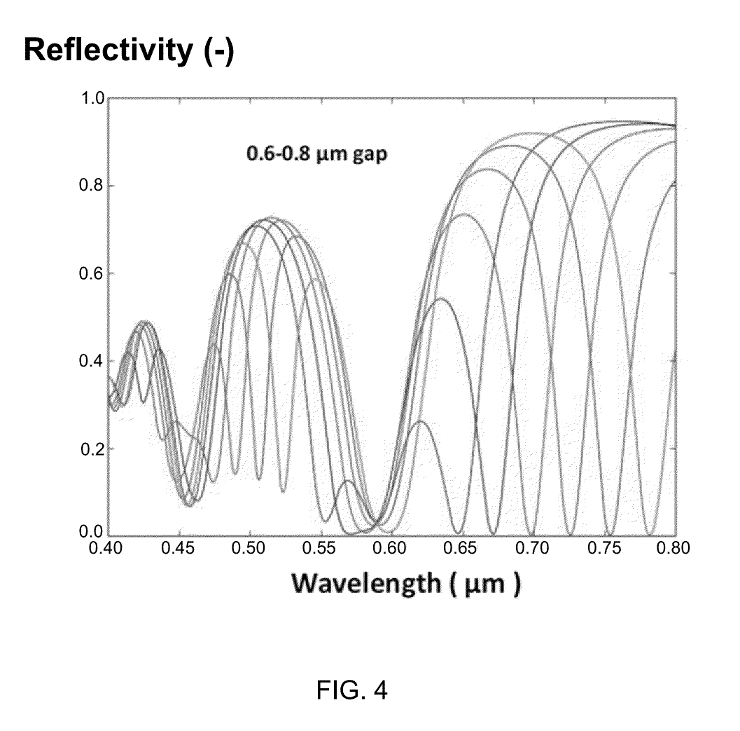

FIGS. 3-4 shows a plot of the reflected light spectrum under normal incidence for two different gaps. Note that the spectral curve shift is proportional to the gap. If the particle has cylindrical symmetry with diaphragm of radius a, thickness t, Young's modulus E and Poisson's ratio, the deflection is roughly equation (3) below.

FIG. 3 shows a plot of the reflected light spectrum under normal incidence for two different gaps with T_{d}=0.7 and R_{d}=(1−T_{d})=0.3. Note that, as described above, the spectral curve shift is proportional to the gap and that the reflectance is zero when λₘᵢₙ=g(ΔP).

If the particle has cylindrical symmetry with diaphragm radius a and thickness t, the particle gap change under pressure is:

g(ΔP)≈g₀−2·d(ΔP) (2)

d(ΔP) is the deflection of each diaphragm. If the particle has cylindrical symmetry with diaphragm of radius a, thickness t, Young's modulus E and Poisson's ratio v, the deflection is roughly:

$$\frac{Δ P \cdot {a}^{4}}{{Et}^{4}} = \frac{16}{3 ( 1 - {v}^{2} )} ( \frac{d}{t} ) + \frac{( 7 - v )}{3 ( 1 - v )} ( \frac{{d}^{3}}{{t}^{3}} ) \qquad ( 3 )$$

Therefore the thickness and radius of the diaphragm can be adjusted to tune the specific pressure range of interest. The particle gap is adjusted to determine the spectral region of the detection instrumentation. In the optical visible range, gaps in the 0.4-0.8 μm range can be used for the particle, for example.

The actual calculation of the spectral reflectivity is more complex than that described above because (a) the reflectivity of each diaphragm is a function of wavelength and material and (b) in a real setup there are spurious reflections from additional surfaces than must be accounted for. Computer simulation of the reflectance under more realistic circumstances utilizing wavelength-dependent refraction indexes of its various constitutive materials (using the SOPRA spectroscopic elipsometry database) is shown in FIG. 4 for a particle with 0.2 μm polysilicon walls trapped inside a PDMS-chip channel in an aqueous environment. While the reflectance curve is attenuated due to the absorption characteristics of the fluid, the main resonance is largely dependent on the smallest gap corresponding to the optical vacuum cavity hence permitting a direct measurement of the pressure on the exterior of the microparticle. Constructed of such particles and conducted tests illustrate this concept as described subsequently herein.

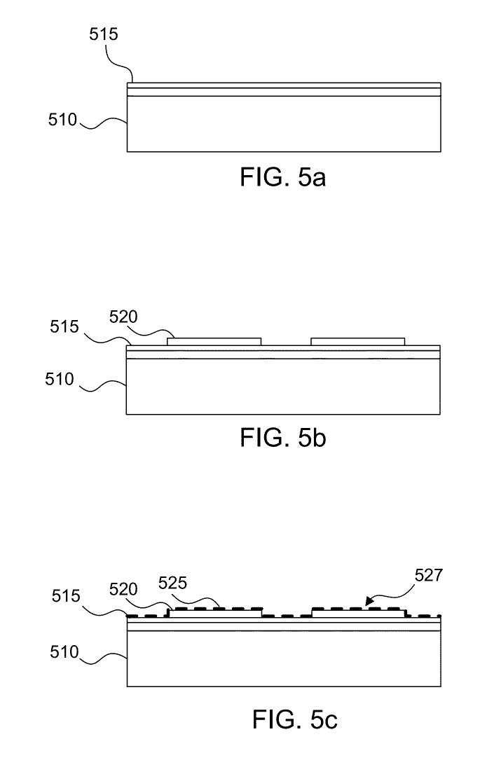

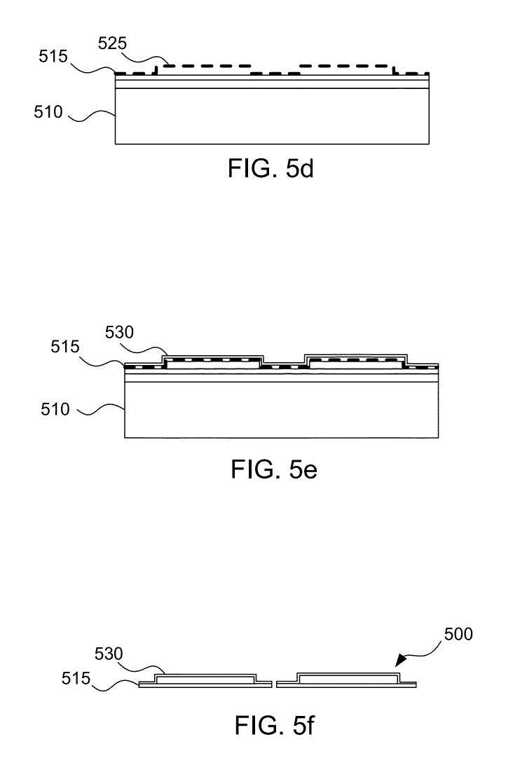

One application of the particles discussed herein is pressure mapping in microfluidic chips, such as binary dilution network chips, for example. Pressure ranges of interests are often between 0-400 kPa (0-60 PSI), and the size of the particle generally speaking should be approximately 10 μm in diameter or smaller. Referring to FIGS. 5a-f, pill-like structures such as those seen in FIGS. 2a-c can be fabricated by surface micromachining methods which involve growth of the bottom diaphragm 515 over a substrate 510 (FIG. 5a). Non-limiting examples of materials for the bottom diaphragm can include silicon, glass and polymers, although other materials can be suitable which provide sufficient mechanical support to the particles. A sacrificial spacer 520 (FIG. 5b) can be deposited and patterned to the desired cavity shape. Non-limiting examples of materials suitable for use as the spacer can include silicon, glass and polymers. Partial deposition of the top diaphragm 525 (FIG. 5c) can allow for subsequent removal of the spacer 520 while retaining the cavity shape. The top diaphragm can typically be formed of the same material as the bottom diaphragm, although different materials can be chosen as long as the interface between the materials is sufficiently secure to maintain the cavity integrity during use. A small orifice 527 (or multiple orifices) can be opened down by etching to the sacrificial layer thus permitting removal of the spacer (FIG. 5d). The removal of the sacrificial oxide and the formation of a cavity can be later verified by breaking the particle top diaphragm. In some aspects, the top diaphragm already comprises holes through which the spacer can be removed, as will be described below. This is followed by sealing the hole by additional material deposition with the remaining thickness of the top diaphragm 530 at a low pressure (FIG. 5e). The particles 500 can then be released, as in FIG. 5E Release can be accomplished, for example, by sacrificial etching. The fabrication of such particles using conventional optical micromachining methods poses significant challenges because the minimum definable features are in the 2 pm range. Nevertheless it is possible to fabricate very small particles in this fashion if submicron lithography is available. Registration errors are also in the same order of magnitude as the sizes of these microparticles. Alternatively, the same structure can be fabricated without using a sacrificial layer using a bonding process such as thermocompression or anodic bonding, but this can also be subject to minimum bond area constraints that can be tailored.

Due to the above limitations, the particles can optionally be fabricated using a simpler method based on a permeable film approach. The process flow is as shown in FIGS. 5a-f. In this approach the top diaphragm is made very thin such that pores or holes are present in the diaphragm. This permits the removal of the sacrificial spacer without patterning additional access holes. After the spacer is removed the pores can be sealed by depositing the rest of the diaphragm thickness. Submicron pores are known to exist in LPCVD polycrystalline silicon (E=160 GPa) under certain conditions when the polysilicon thickness is below 0.1 μm. The pores are completely sealed once the thickness exceeds about 0.15 μm. Adding more of the diaphragm seals the film pores thus forming an hermetically sealed cavity. Other construction methods are also possible.

Based on the constraints and method discussed, in one example a polysilicon diaphragm thickness target of 0.25 μm and a default gap of 0.8 μm can be selected. Using these parameters in Eq. (3), a particle diameter of 10 μm produces a (total) deflection of about 0.18 μm under a pressure excursion of 0-400 kPa.

Using a microparticle pitch of 14 μm this results in a microparticle density of 310,000 particles per square centimeter. On a typical 15 mm diameter wafer a total of ˜50 million particles per wafer substrate can be fabricated and about 1.2 billion microparticles can be fabricated on a single 25-wafer lot.

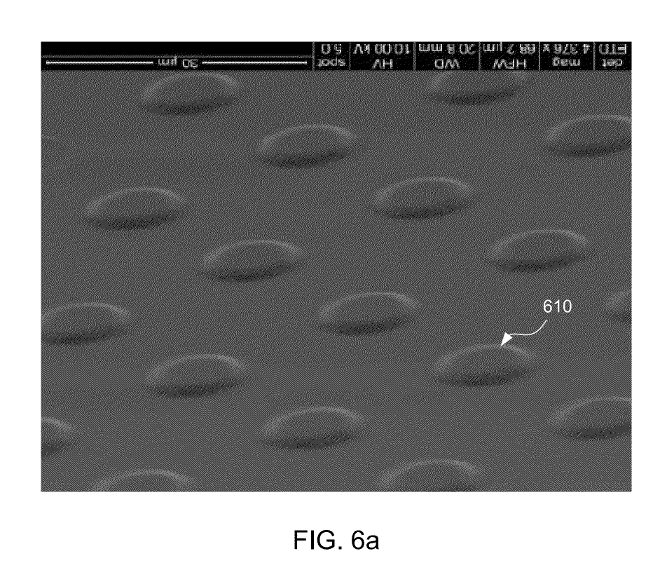

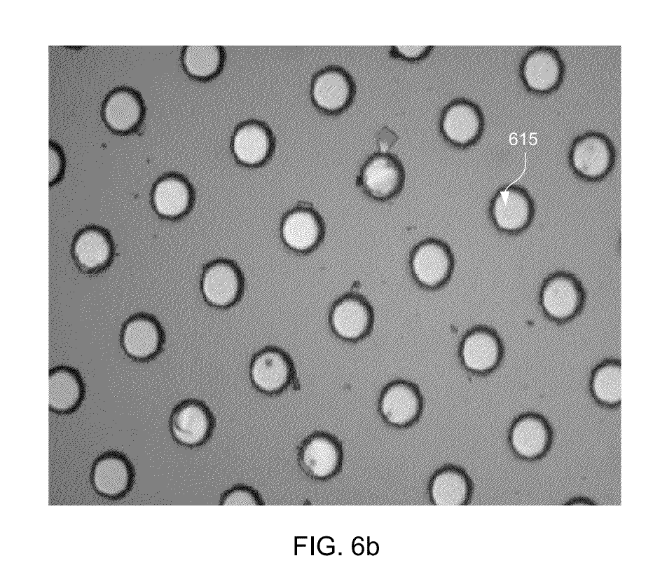

FIG. 6a shows a Scanning Electron Microscope (SEM) photograph of microparticle devices 610 prior to the release. FIG. 6b is an optical photograph of the particles 615 at atmospheric pressure. The particles can display a characteristic green color corresponding to the Fabry-Perot characteristics of the optical resonator. The color is consistent with the calculations of deflection and spectral resonance.

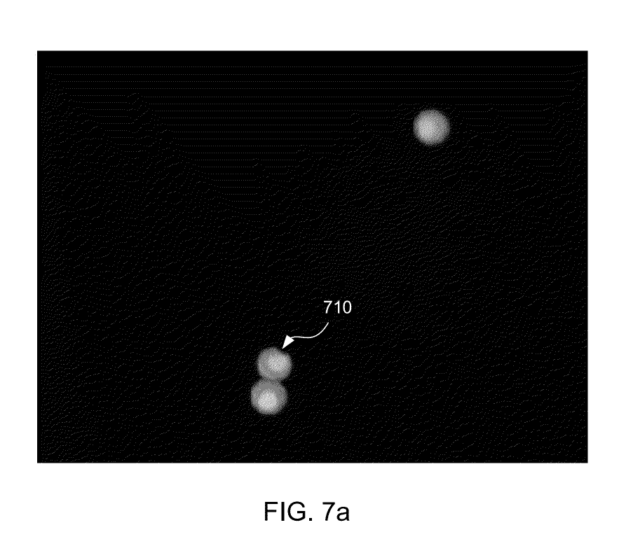

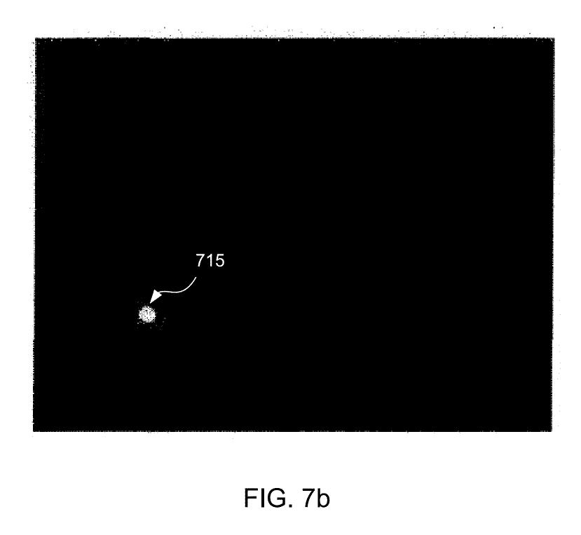

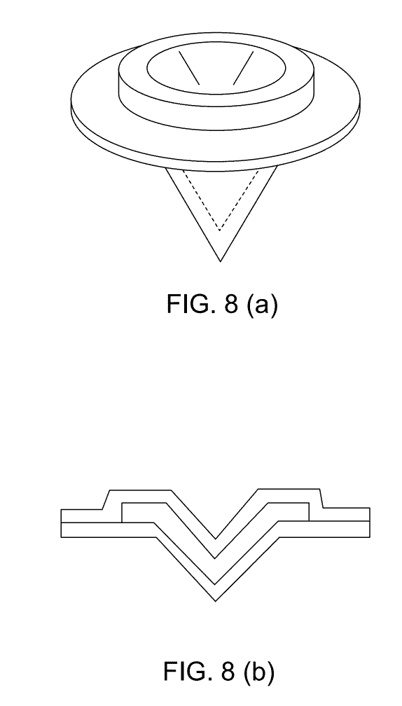

FIGS. 7a-7b shows photographs of 10 μm -diameter pressure-sensing microparticles 710, 715 after they have been released and are floating in a water suspension. The color of the cavity may shift to a yellow tone surrounded by a red ring of the polysilicon seal.

A working process for the planar (slab-type) spectroscopic microparticle has been developed based on the porous polysilicon film construction approach and spectral measurements of the particle reflectivity have been performed. In initial samples, a microparticle pitch of 14 μm was used, resulting in a microparticle density of 310,000 particles per square centimeter. On a typical 150 mm diameter wafer a total of ˜50 million particles per wafer substrate and 1.2 billion microparticles on a single 25-wafer lot can be constructed simultaneously. Reflectivity spectra for the particle has also been measured as a function of wavelength using a microscope attached to an ocean-optics VIS-IR spectrograph. During the measurement, the microscope was focused at the center of a diaphragm under atmospheric conditions and the light from the remainder of the field was blocked out. The measured spectral characteristics of the diaphragm reflectance were in good agreement with the calculated spectra.

Under Aim I, the design of a family of pressure sensitive spectroscopic particles of different types is provided. In this task, slab-type particles, particles with retroreflectors and spherical spectroscopic particles can be formed. The difference of these type of particles resides on the angular dependence of the spectral reflectivity. While the spectral reflectance characteristics of these particles are exclusively dependent on the particle cavity shape, the magnitude of the reflected intensity is dependent on the orientation of the particle respect to the incident light. Since in general the orientation of the particle respect to the light source is random, a narrow high-reflectivity capture range will result on a very small fraction of the particles displaying a visible resonance. These particles can be designed with increasingly higher angular resonance capture range. The simplest structure with the smallest range is the slab-type.

The simplest-type of spectroscopic particle is a slab. In this particle, incident light bounces back and forth between two parallel surfaces, in essence forming a miniature, free floating Fabry-perot resonator. The analysis of the reflectance characteristics of such structure is readily available. Each pressure sensing particle consists of a hollow pill-like cavity of micrometer dimensions. The cavity is bounded by thin diaphragm walls spaced by gap gas shown in the figures and described above. The interior of the cavity is hermetically sealed at very low pressure hence acting as a vacuum reference. If the external pressure of the particle is larger than the reference cavity pressure the diaphragms deflect thus changing their separation gap. This gap can be measured optically. The device diaphragms form a Fabry-Perot resonator or etalon of characteristic gap gP. In a simple Fabry-Perot resonator, at normal incidence the optical reflectance as a function of wavelength is equation (1):

$$R ( λ ) = \frac{1}{1 + \frac{{T}_{d}^{2}}{4 {R}_{d}} \cdot {csc}^{2} ( \frac{2 π g}{λ} )}$$

where T and R are the diaphragm transmission and reflection coefficients, and gP is the pressure dependent gap. Therefore the thickness and radius of the diaphragm can be adjusted to tune the specific pressure range of interest. The particle gap is adjusted to determine the spectral region of the detection instrumentation. In the optical visible range, gaps in the 0.4-0.8 μm should be used for the particle for example. The actual calculation of the spectral reflectivity is more complex than that described above because (a) the reflectivity of each diaphragm is a function of wavelength and material and (b) in a real setup there are spurious reflections from additional surfaces than must be accounted for.

In the slab structure, the optical resonance of Eq. (1) is observed at normal incidence. If the incidence angle deviates from normal incidence, the main resonance occurs when the reflectance is zero. Therefore for accurate results the numerical aperture (NA) of the optical system should be small. Any angular deviation from incidence beyond the numerical aperture results in an opaque reflection. Since the particle orientation respect to the microscope is not controlled, statistically only a very small fraction of these particles will be aligned with the microscope and displaying the resonance. This is a problem in most environments except in shallow two dimensional flows such as those present in microfluidic chip channels. For this reason the slab-type particle is expected to be useful in a limited set of applications.

In order reduce the angular dependence of the reflectivity construction of (a) cavity resonator particles with retroreflectors and (b) spherical spectroscopic particles is discussed in the sections below.

Spectroscopic Particles with Built-In Retroreflectors:

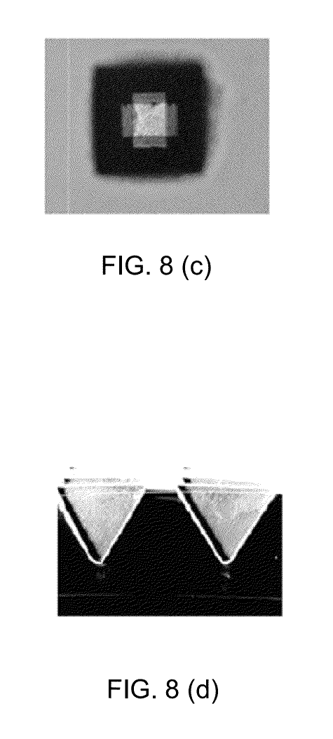

Retroreflectors are often used in optical systems to improve the efficiency of reflected light collection. A retroreflector is a device or surface that reflects light back to its source with a minimum scattering of light. The device or surface's angle of incidence is greater than zero. This is unlike the slab planar type mirror, surface which does so only if the mirror is exactly perpendicular to the wave front, having a zero angle of incidence. A simple type of retroreflective surface is a cube corner reflector for example. Such retroreflective-like surface can be added to the slab particle basically by constructing the slab cavity on a shaped geometrical concave surface. This can be constructed for example by simply building the microparticle over an anisotropically-etched cavity such as commonly formed by potassium hydroxide (KOH) etching of silicon substrates as shown in FIGS. 8a-d. The utilization of such fabrication technique can be used to implement retroreflective spectroscopic particles. The angular spectral reflectance can be calculated numerically and optimized for pressure sensing applications. Retroreflective surfaces can be constructed on top of pitted surfaces in order to construct quasi-retroreflective spectroscopic particles. Also, pitted quasi-retroreflectors can be constructed using anisotropically etched inverted pyramid pits on silicon. Specifically, FIG. 8a is a perspective line drawing of a retroreflective particle, FIG. 8b is a cross-sectional side view of the particle of FIG. 8a, FIG. 8c is a SEM image of a top view of a retroreflective particle, and FIG. 8d is a photograph of a side view of a retroreflective particle.

Isotropic Spherical Spectroscopic Particles:

Retroreflectors can provide a higher particle reflectivity over a wider range of incidence angles. Ultimately the construction of pressure-sensing particles that have reflectance characteristics independent of the observation angle or particle orientation can be desirable. Such particles are typically spherical.

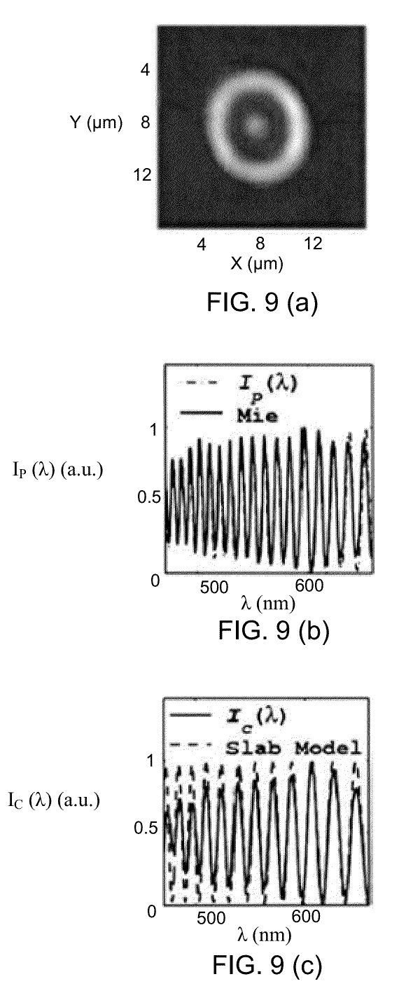

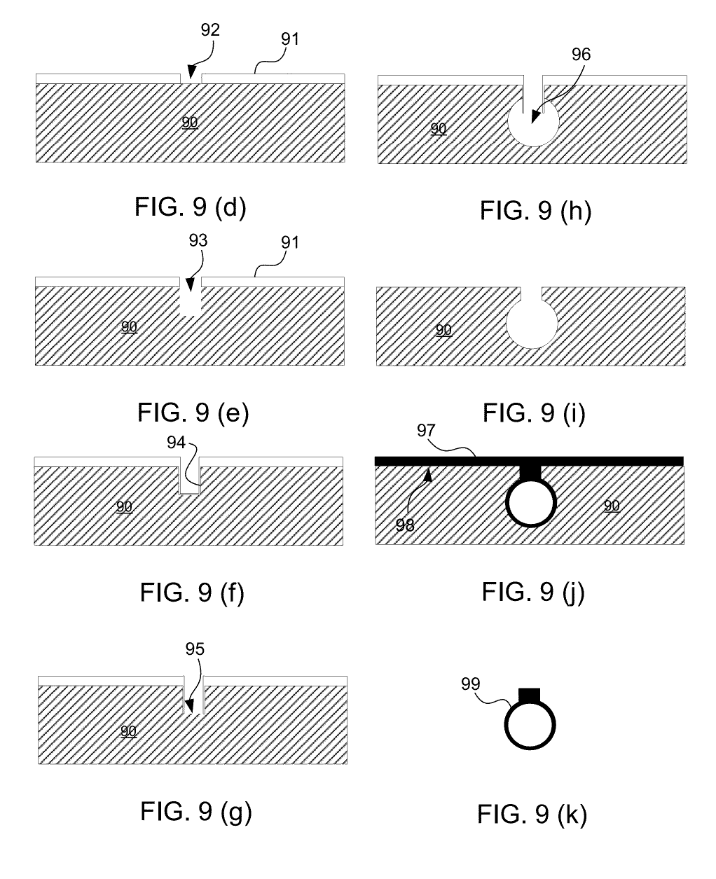

The light scattering characteristics of spherical particles can be determined by complex Mie theory (see FIG. 9b), but recent observations of the reflectance of spherical particles (see FIG. 9a) indicate that the spectral reflectance at the center of the sphere (hence at normal incidence) follows closely the reflectance of a slab resonator of thickness equal to the sphere diameter (see FIG. 9c).

The primary difficulty with this type of hollow spherical particle is its mechanical design. The sphere wall dimensions can be designed to permit expansion and shrinkage of the sphere without causing buckling. The fabrication process for such structures does not involve any lithographic process. In one option, porous polysilicon can be coated on top of a fused silica microsphere. The fused silica is next sacrificially removed through the porous film and finally sealed with an extra deposition of polysilicon. The method does not require lithography but the deposition involves fluidization of the silica particles in a CVD (chemical vapor deposition) reactor. Similar schemes can be worked for other sacrificial and coating layers. A wide variety of materials can be used for the shell particularly focusing on materials with a low Young's modulus.

Spherical particles can be useful since particle orientation does not affect illumination responses such that spherical particles can readily be used in planar and non-planar fluid flows. Variations in pressure conditions result in changes in particle volume and diameter. One option for formation of spherical particles is shown in FIG. 9(d) through 9(k). The spherical particles can be batch fabricated on a silicon substrate 90 (such as a silicon wafer), as shown in FIG. 9(d) by the deposition of 0.5 μm thermal oxide 91 on the silicon substrate. Arrays of circular holes 92 are next patterned in the oxide layer 91. As shown in FIG. 9(e), 10 μm deep trenches 93 are etched using DRIE. The trenches 93 are coated with 0.1 μm thermal oxide 94 as shown in FIG. 9(f). The oxide at the bottom of the trench is next etched away using RIE as shown in FIG. 9(g) to leave an exposed silicon surface 95. The oxide coated long and narrow trench thus forms a long tunnel that serves a point source buried in the silicon. Next XeF₂ isotropic etchant is introduced into the channel diffusing away from the hole and thus gradually etching spherical cavities 96 as shown in FIG. 9(h). The rough surface finish of the XeF₂ etched-silicon can be further smoothed by oxidation and BHF etch which also removes the oxide material as shown in FIG. 9(i). This can be followed by deposition of a thin layer of polysilicon which can facilitate a neck down of the trench opening. As illustrated in FIG. 9(j) a layer of parylene 97 can be deposited that forms the particle shell and completely fills the trench forming a supporting beam 98. In FIG. 9(k), the top parylene film and most of the support beam are etched in O₂ plasma while the spherical particles 99 are released from their substrate using a XeF₂ etchant. The shell thickness and radius are selected such that the parylene forms a pin-hole free barrier while producing a detectable radius change with pressure. The particle diameter can be varied by changing the trench depth, etching time, and other factors. Similarly, the shell thickness can be varied by adjusting deposition times and the like. Thus, although specific materials and dimensions are exemplified in the above description, alterations in materials and dimensions can be made consistent with these concepts. For example, any etchable material can be used as a substrate and the particles can be formed of any suitable materials which can be deposited and which flexibly respond to pressure changes. Back scattering produced by illumination of the particles can then be correlated with particle size as discussed herein (e.g. scattering lobe spacing is roughly inversely proportional to particle radius).

Methods for Mass Production of Low-Cost Pressure Sensing Particles:

Microfabrication methods were developed for the high volume production of the spectroscopic particles. The primary use of the particles discussed is for pressure mapping in micro fluidic chips. Pressure ranges of interests are between 0-400 kPa (0-60 PSI), and the size of the particle generally speaking should be approximately 10 μm in diameter or smaller.

Slab-Type Spectroscopic Particles: Pill-like structures such as those illustrated in FIGS. 5a-f can be fabricated by surface micromachining methods which involves growth of the bottom diaphragm, deposition and patterning of sacrificial spacer followed by partial deposition of the top diaphragm. A small orifice can be opened down to the sacrificial layer thus permitting removal of the spacer. This is followed by sealing the hole with the remaining thickness of the top diaphragm at a low pressure. The fabrication of such particles using conventional optical micromachining methods poses significant challenges because the minimum definable features are in the 2 μm range. Nevertheless it is possible to fabricate very small particles in this fashion if submicron lithography is available. Registration errors are also in the same order of magnitude. Alternatively the same structure can be fabricated without using a sacrificial layer using a bonding process, but this can also subject to minimum bond area constraints that must be experimented with. Due to the above limitations, the polysilicon particles can be fabricated using a much simpler method based on the permeable film approach.

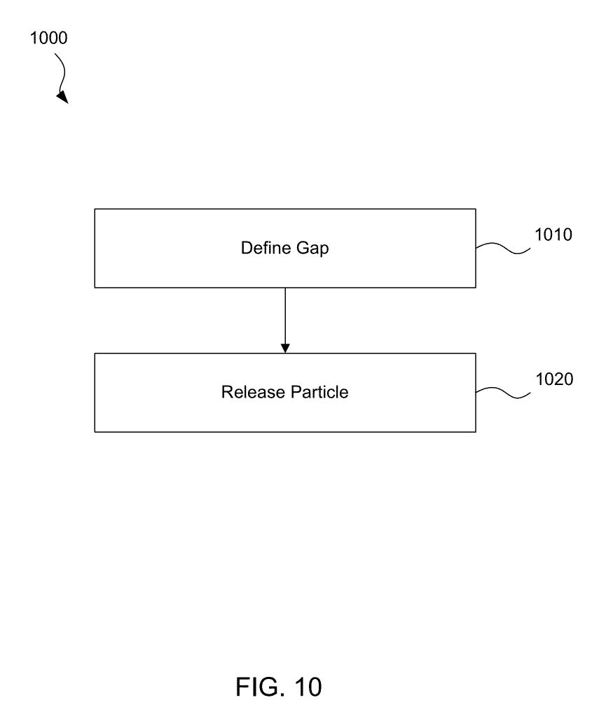

In FIG. 10, microparticles can be batch fabricated on silicon wafers. The process flow 1000 can use just two lithography steps. The first step 1010 is used to define the initial cavity gap, and the second step is to release 1020 the particle from its carrier substrate. The process starts with the growth of 0.6 μm of thermal oxide on silicon followed by 0.15 μm of undoped polysilicon. The particle cavity is formed by the deposition of 0.7 μm of PEVD oxide and wet 6:1 BHF etching. Next the cavity oxide spacer is sealed with a 0.1 μm of porous polysilicon. This material has small pores that permit the sacrificial etch of the spacer oxide in concentrated HF. Next a 0.05 μm layer of regular polysilicon is deposited to seal the cavity at the deposition pressure of the polysilicon sealing film (˜200 mT). In the final step, the periphery of the particle is lithographically defined and the polysilicon is etched down to the underlying oxide. The particles can be released by sacrificial etching of the bottom oxide in concentrated HF. The particles are collected via a series of gradual dilutions in de-ionized H₂O. The particle density is slightly lower than the density of H₂O. A final dilution in methanol produces microparticles in solution.

In this approach the top diaphragm is made very thin such that pores or holes are present in the diaphragm. This thin polysilicon permits the removal of the sacrificial spacer without patterning additional access holes. After the spacer is removed the pores can be sealed by depositing the rest of the diaphragm thickness. If the top diaphragm film is very thin it is permeable thus permitting the removal of the sacrificial spacer film. Adding more of the pores are known to exist in diaphragm seals the film pores thus forming an hermetically sealed cavity. Other LPCVD polycrystalline silicon construction methods discussed in the text are also possible. (E=160 GPa) under certain conditions when the polysilicon thickness is below 0.1 μm. The pores are completely sealed once the thickness exceeds about 0.15 μm. Based on the constraints and method discussed above we selected a polysilicon diaphragm thickness target of 0.25 μm and a default gap of 0.8 μm. Using these parameters in Eq. (3), a particle diameter of ˜10 μm produces a (total) deflection of about 0.18 μm under a pressure excursion of 0-400 kPa. We have fabricated slab-type pressure sensing particles using this scheme.

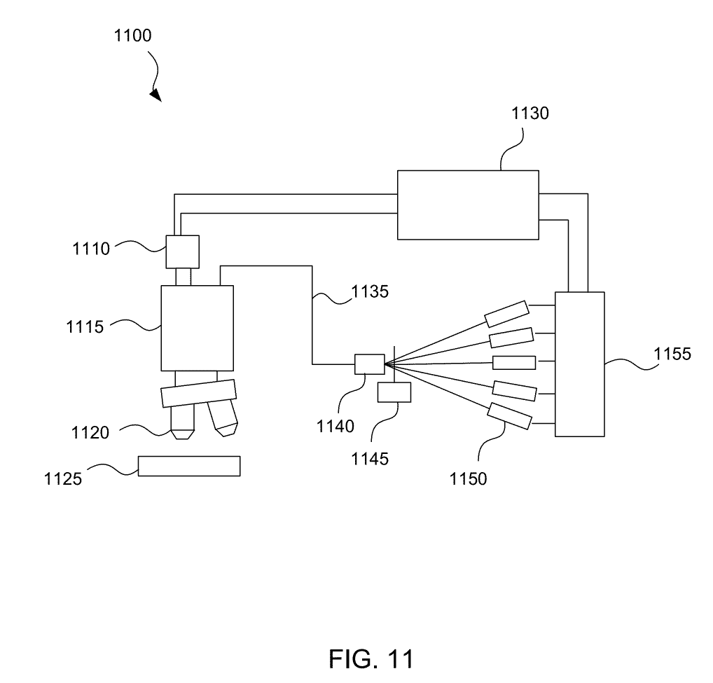

FIG. 11 shows a schematic of the system 1100. It includes (1) a high speed digital camera 1110 with an external trigger attached to a conventional probe station microscope 1115 and a programmable pulsed light source 1150. High-speed digital cameras are readily available (though very expensive ˜$22K) for motion analysis such as the vision research Miro eX-2 (vision research). Such a camera can digitally record 320×240 digital images at 4700 frames per second because it has its own buffering memory. A Signatone S250 prober can be used with Mitutoyo microscope. The sample 1125 (such as a microfluidic chip) is illuminated via a fiber guide 1135 coupled to the pulsed light source and is viewed through an objective 1120 of the microscope. The light source consists of a series of collimated solid-state laser diode light beams coupled to the prober illumination fiber guide (and optional filtered LEDs). The pulsed light sources provide illumination at constant wavelength for a brief period of time, as short as a few μs, synchronized with the camera electronic shutter control. As many as nine or more different wavelength-lasers can be used which are readily available. Experiments with systems at frame rates up to 5000 fps have been performed. A computer 1130 can be used to store images captured by the camera, to trigger the camera and to trigger a pulsed current driver 1155 which enables pulsing of the laser diodes. A vibrating piezo 1145 and a diffuser 1140 can also be used to modulate and diffuse the pulsed light.

Illumination schemes to produce a reasonable image at single wavelength with the laser scheme coupled to the fiber guide, and it was determined that good quality pictures can be taken using a shallow angle (˜5 deg.) coupling scheme for the laser with optical power of about 10-20 mW coupled through a vibrating despeckler filter. Coupling of multiple wavelengths is easily achieved without need of complex beam combiners simply by mounting the lasers on a wheel in a radial configuration at a shallow entry angle to the fiber guide. The recording of the specific wavelength image and wavelength selection can be controlled by a computer interface. Because the power of the light sources can drift over time and the recording camera also has a characteristic spectral response, it is necessary to adjust the power of each laser individually. These adjustments can be done by tapping on the microscope light and feeding this into an Ocean Optics 4000 fiber spectrometer to continuously monitor the source power. Such spectrograph can also be triggered in sync with the pulsed light source.

Once digital images of the particles are recorded at several wavelengths, the spectrum can be reconstructed and the observed resonance can be fitted to a smooth reflectance function which ultimately can be related to the resonance and the pressure at the particle. In order to map pressure over the entire microfluidic chip, the chip surface can be scanned by the prober.

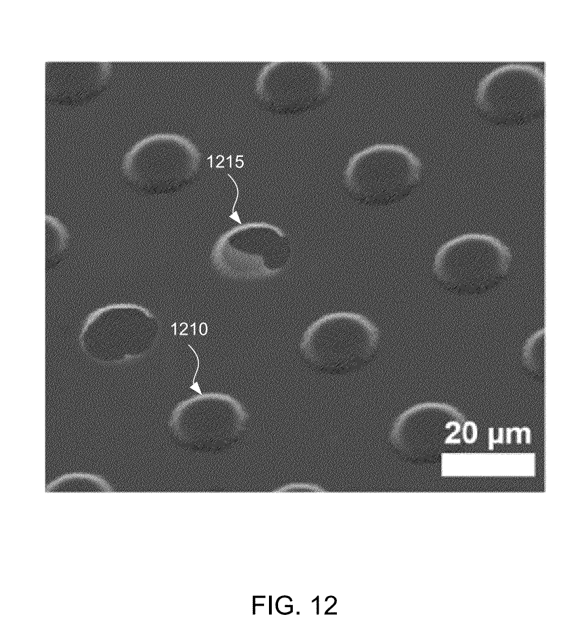

FIG. 12 shows an SEM photograph of a slab-type microparticle array on a carrier silicon substrate with a density of 310,000 particles per square centimeter. The particles shown in FIG. 12 are slab-type 12 μm-diameter spectroscopic pressure-sensor sensor particles. Since the SEM photograph is of the microparticle array on the substrate, the particles have not yet been released. Also noted is that the SEM photograph can show when particles are sealed 1210 and when the shell is broken 1215.

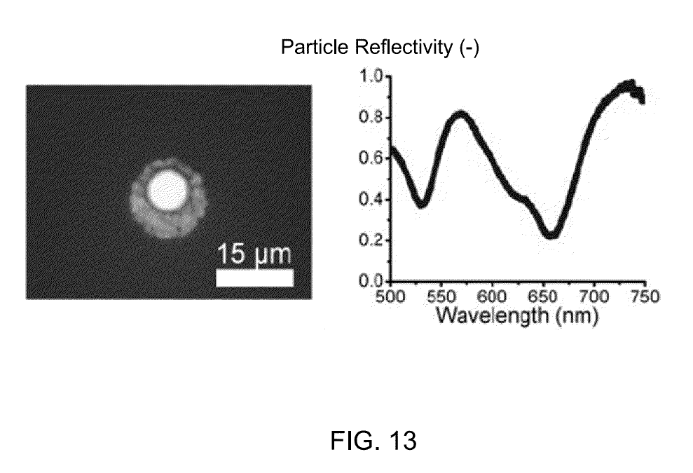

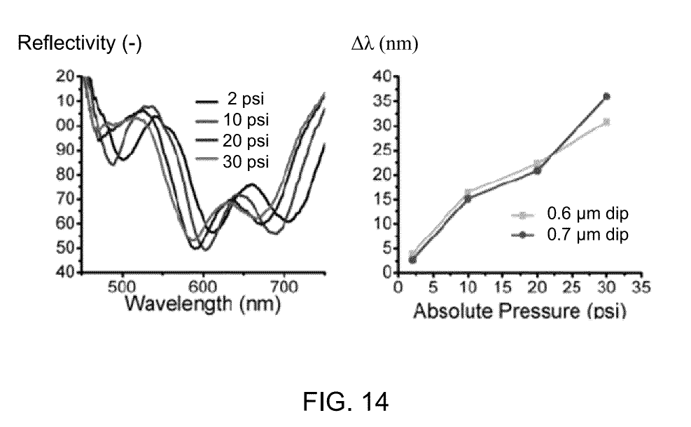

FIG. 13 shows an optical photograph of a released 0.7 μm-gap, 14 μm-diameter slab microparticle on a glass substrate, and the corresponding optical reflectance at atmospheric pressure measured using an Ocean Optics spectrometer attached to a microscope. The particle reflectance shows characteristic dips at 0.52 and 0.65 μm. FIG. 14 shows the pressure dependence of a microparticle reflectivity. The spectral dip change can be correlated to the pressure-dependent compression of the optical cavity.

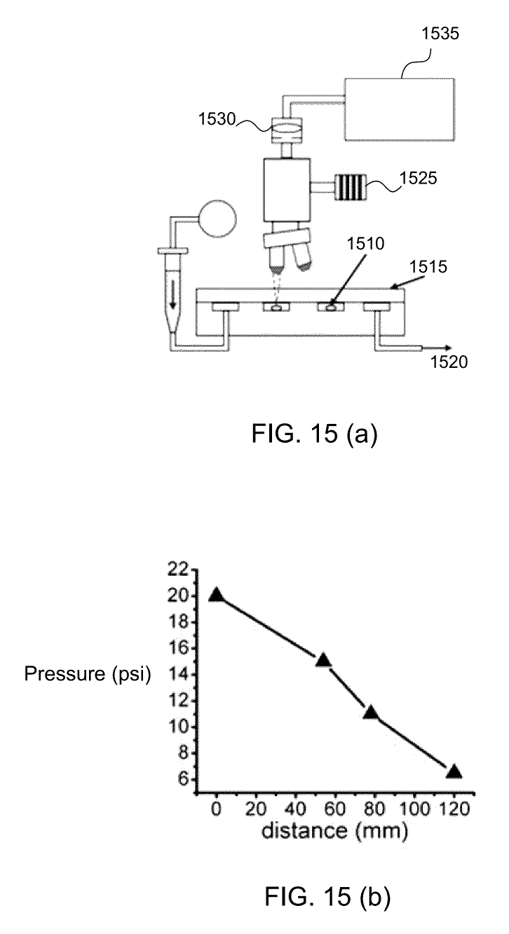

In order to demonstrate the utilization of these devices a large number of microparticles were introduced inside a test PDMS microfluidic chip with a 100×25 μm² cross section which adhere to the capillary walls. The particle reflectivity was measured using the setup shown in FIG. 15a under a constant pressure driven flow of 3 cm/s. The setup includes an aperture and lens 1530, Ocean Optics USB 4000 1535, an illuminator 1525, and particles 1510 in a PDMS chip covered by a glass cover 1515. Fluid flows through the chip from the left to the drain 1520 at the right. FIG. 15b shows the microparticle measured pressure drop vs. distance from the inlet. The measurements indicate an approximate linear pressure drop vs. distance.

Retroreflective Spectroscopic Particles:

The procedure for the fabrication of retroreflective particle is almost identical, but the starting surface is a KOH self-limited pit for each particle. The depth of the inverted pyramid structure is self-limiting hence the angle of the retroreflective surface is precisely controlled.

Spherical Spectroscopic Particles:

The fabrication process for such structures does not involve any lithographic process. In one option, porous polysilicon can be coated on top of readily-available monodisperse fused silica microspheres. The fused silica is next sacrificially removed through the porous film and finally sealed with an extra deposition of polysilicon leaving a hollow spherical resonator cavity. The method does not require lithography but the deposition requires fluidization of the silica particles in a CVD reactor. Similar schemes can be worked for other sacrificial and coating layers. A wide variety of materials can be suitable for the shell particularly focusing on materials with a low Young's modulus and low-leak rate polymers as governed by the previously discussed relationships. Non-limiting examples can include PTFE, PVDF, perylene, and other materials which may incorporate gas barrier layers. Materials having a relatively low Young's modulus allow for measurable deflection of the particle wall for a given pressure difference across the wall. A lower Young's modulus results in higher sensitivity, while such materials also tend to become more permeable to gases. Optional coating and/or gas barrier layers (aluminum oxide, metal oxides, etc) can be included to mitigate such effects for low Young's modulus materials. As a general guideline, the Young's modulus can be less than 1 GPa, in some case less than 500 MPa, and in other cases from about 1-100 MPa. However, useful Young's modulus can depend on the desired sensitivity and particle configuration.

Spectroscopic Micro-PIM Instrumentation Demonstration System:

The practicality of the microparticle sensing can be tested using a custom optical instrument. A high speed optical instrument that is capable of reading out the optical spectrum of the reflected light from an assembly of spectroscopic particles at very high speeds on a two dimensional field can be used. As a test platform an instrument specifically designed for micro-PIM applications in microfluidic environments can be used. In the micro-PIV system the field of view can be small, approximately 1-2 mm in length. Using typical micro flow velocities of 1 cm/s, a 10 μm wide particle will traverse its own length in 1 ms and the entire filed in about 100-200 ms. The design of such instrument thus poses new challenges as basically the capabilities for the measurement of spectroscopic two-dimensional images in millisecond does not exist as present spectroscopic imaging systems require slow mechanical scanning of 1D domains (alternatively the instrument could be provided with a single line scan capability). In a basic approach, entire field images can be recorded using a series of pulsed high-speed laser or narrow-filtered pulsed LEDs to produce a series of high-speed, single-wavelength photographs of the same “frozen” flow field.

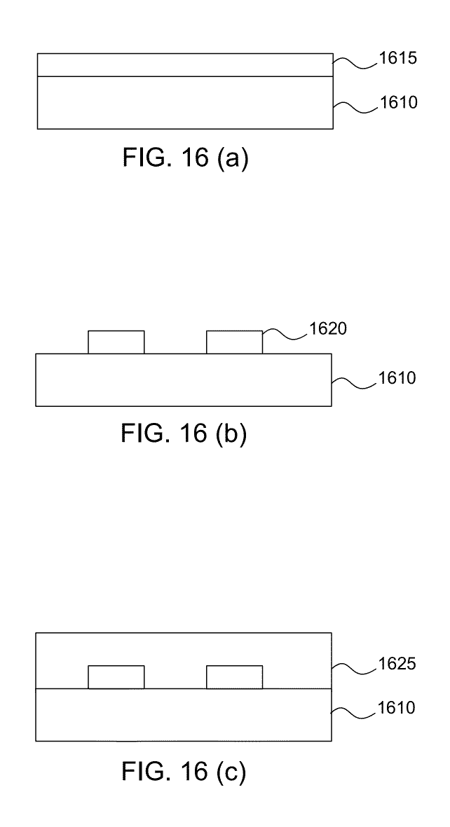

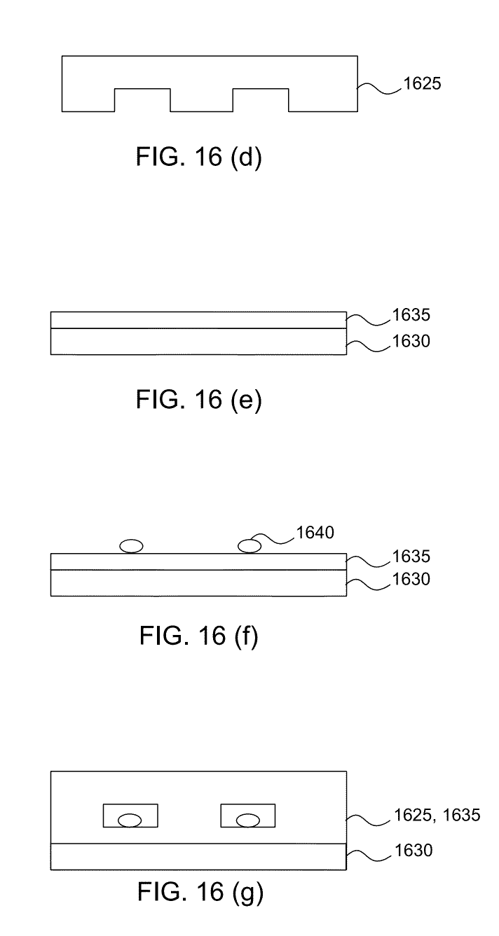

In accordance with embodiments, the microparticles can be used within microfluidic chips. In order to use the microparticles within microfluidic chips the particles can be embedded within a thin layer of PDMS, as shown in the process of FIGS. 16a-g. The thin layer can be attached to a glass slide substrate followed by conventional processing of one or two-layer PDMS chip construction. Specifically, FIG. 16a shows an AZ9260 thick film photoresist 1615 deposited over a substrate 1610. The photoresist is patterned as in FIG. 16b, such as by conventional mold patterning, leaving a patterned photoresist 1620. A PDMS layer 1625 is deposited over the patterned photoresist as in FIG. 16c and then can be separated from the substrate and photoresist as in FIG. 16d, leaving voids in the PDMS where the patterned photoresist had been. FIG. 16e shows a quartz slide 1630 prepared with a layer of PDMS 1635 deposited thereon. Pressure sensitive microparticles 1640 can be placed over the PDMS layer 1635 as shown in FIG. 16f. The PDMS layer 1625 can then be placed over the other PDMS layer 6135 as in FIG. 16g such that the microparticles are enclosed within the void in PDMS layer 1625 and between the two PDMS layers.

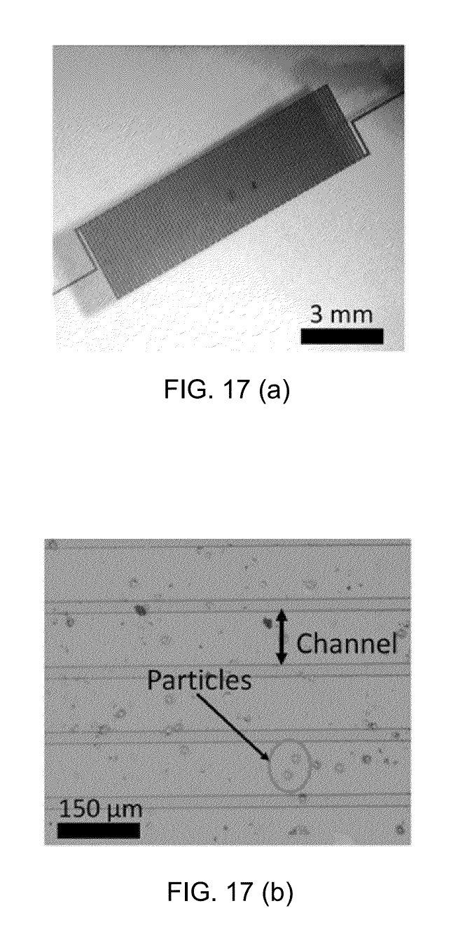

FIGS. 17a-b shows photographs of an example PDMS chip with embedded particles inside the lower channel wall at random locations along a long serpentine channel. The right-hand photograph in FIG. 17b is a zoomed in view of the PDMS chip shown in FIG. 17a and shows the pressure sensing microparticles embedded on the channel wall at random locations. With slab-type microparticles, embedding the particles in a wall of a fluid channel can ensure that light can be reflected off of the particle diaphragm to produce accurate measurements.

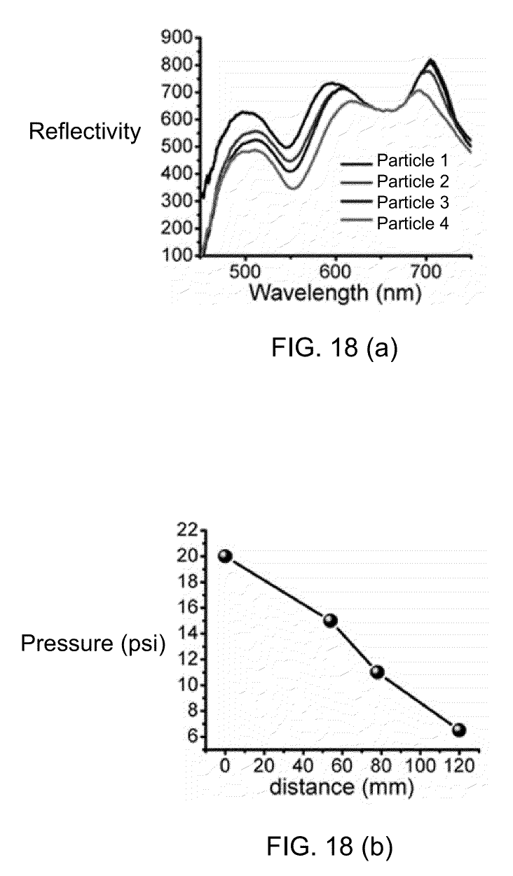

FIG. 18a shows the spectral characteristics of four different microparticles at different locations observed from the glass side under a flow of 3.5 cm/s displaying different spectra shift corresponding to the pressure at their respective locations. FIG. 18b shows the conversion of the shift into pressure versus particle location from the inlet. The measurements indicate an approximate linear pressure drop vs. distance.

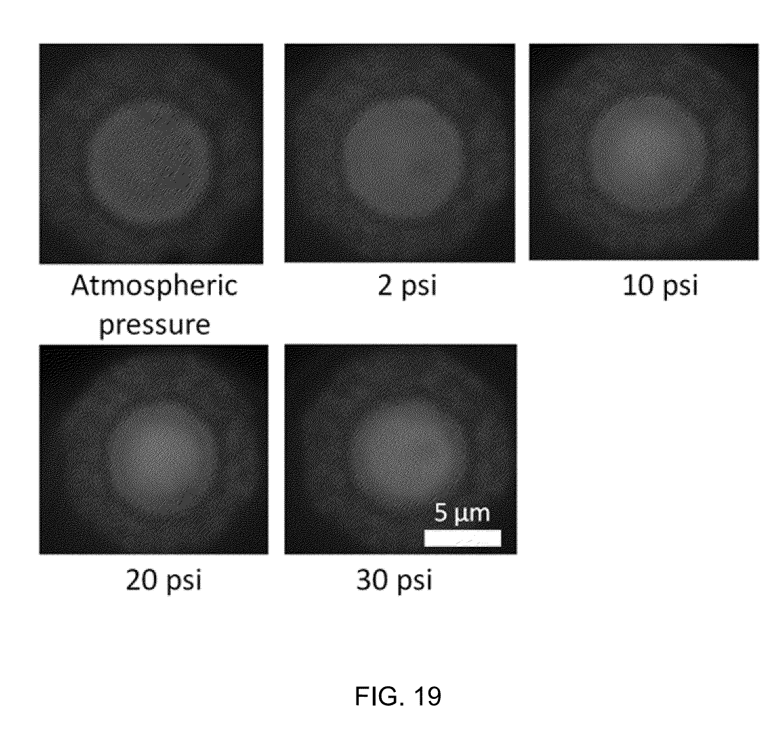

As described above, change in cavity gap causes a corresponding and consistent shift in resonance from a particle. A color (or wavelength) of light reflected from the particles can be used to determine the pressure. FIG. 19 shows the observed particle color changes versus external pressure for a single particle.

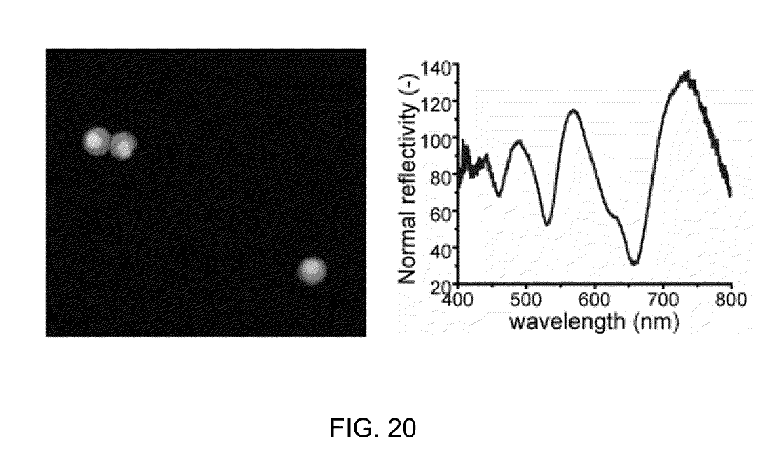

FIG. 20 shows an optical photograph of three released 0.7 μm-gap, 14 μm-diameter slab microparticles in water suspension, and the corresponding optical reflectance at atmospheric pressure measured using an Ocean Optics spectrometer attached to a microscope. The particle reflectance shows a characteristic dip between 0.6 and 0.7 μm. The graph illustrates experimental measurement of slab microparticle reflectivity at normal incidence in air. The spectrum on the graph clearly shows the main optical resonance at 650 nm, which is in agreement with theoretical calculations.

The micro-particles particles described herein can be used to measure pressure in larger flow domains such as those present in aerospace applications. Lower cost microparticles for example can be fabricated in a sub-micron standard CMOS foundry on larger size wafers.

For fifty years, Particle Imaging Velocimetry (PIV) has been widely used for experimental characterization of open and closed flows in a wide field of applications ranging from aircraft surface design to medical devices. A flow field however is not only specified by its pointwise velocity but by also its pressure. Up to date there has been no widely available parallel “snapshot” measurement technique to measure the pressure field in a flow.

The batch fabrication and test of artificial optical resonator slab-type micro particles (14 μm diameter, 0.7 μm gap, for example) is presented as a means to map absolute pressure within microscopic environments. The pressure-sensing particles consist of a semi-transparent elastic polysilicon shell enclosing a reference vacuum cavity. The optical resonance frequency and the corresponding external pressure can be interrogated optically via reflectivity measurements. The particles can be used in the measurement of internal pressures (such as between 0-20 psi, for example) within microfluidic environments.

There are numerous applications of Particle Imaging Manometry (PIM). The above approach can provide a technological platform for low-cost and massively parallel platform for measurement of flow and pressure fields using engineered spectroscopic “sensing” particles. Such general capability can provide future wide-spread usage of parallel “particle sensing” schemes in diverse biological, environmental and clinical applications for physical and chemical sensing over a broad range of distributed domains.

While the forgoing examples are illustrative of the principles of the present invention in one or more particular applications, it will be apparent to those of ordinary skill in the art that numerous modifications in form, usage and details of implementation can be made without the exercise of inventive faculty, and without departing from the principles and concepts of the invention. Accordingly, it is not intended that the invention be limited, except as by the claims set forth below.

1. A microparticle for use in measuring characteristics of fluid flow, comprising:
at least one flexible wall which is configured to deflect when an outer pressure on an outer side of the wall is different than an inner pressure on an inner side of the wall; and
a void enclosed by the at least one wall and configured to change shape as the wall deflects, and wherein the microparticle has a largest dimension less than about 10 μm.

2. The microparticle as in claim 1, wherein the flexible wall comprises a substantially impermeable wall.

3. The microparticle as in claim 1, wherein the microparticle comprises a substantially spherical shape.

4. The microparticle as in claim 1, wherein the flexible wall comprises a plurality of layers of a common material, wherein a first layer of the plurality of layers comprises a thin holey layer and a second layer of the plurality of layers is thicker than the first layer and is configured to cover holes in the first layer.

5. The microparticle as in claim 1, wherein the flexible wall comprises a reflective surface configured to reflect incident light.

6. The microparticle as in claim 5, wherein the reflective surface is a retroreflective surface having a conical shape.

7. The microparticle as in claim 1, wherein the largest dimension is less than about 2 μm.

8. The microparticle as in claim 1, wherein the flexible wall has a thickness of about 0.25 μm or less.

9. A system for measuring fluid flow characteristics comprising:
a fluid configured to flow in a defined space;
a plurality of pressure sensitive microparticles of claim 1 distributed within the fluid;
a light source configured to illuminate the pressure sensitive microparticles disposed in the fluid, wherein the light source is configured to emit light at a predetermined incident wavelength; and
a detector configured to detect a reflected wavelength of light reflected from the pressure sensitive microparticle.

10. The system as in claim 9, further comprising a pressure analyzer configured to compare the incident wavelength with the reflected wavelength to determine an amount of deflection of the wall of the pressure sensitive microparticle, and to calculate a fluid pressure of the fluid based on the amount of deflection of the wall.

11. The system as in claim 9, wherein the light source comprises a scanning light source configured to scan across the fluid to illuminate the fluid at a plurality of positions.

12. The system as in claim 9, further comprising a flow analyzer configured to detect fluid flow characteristics based on a plurality of flow positions of the pressure sensitive microparticle within the fluid as detected by the detector.

13. A method for creating pressure sensitive microparticles for measuring fluid flow characteristics, comprising:
providing a sacrificial spacer;
forming a thin membrane around the sacrificial spacer such that the membrane comprises pores;
removing the sacrificial spacer from within the thin membrane through the pores to form a void within the thin membrane; and
depositing a sealing membrane around the thin membrane in a low-pressure environment to seal the void by sealing the pores and to create a predetermined internal pressure within the void.

14. The method as in claim 13, wherein the thin membrane and the sealing membrane are formed such that a largest dimension of the pressure sensitive microparticle is less than about 10 μm.

15. The method as in claim 13, further comprising embedding the pressure sensitive microparticles for measuring fluid flow characteristics within a wall of a channel for fluid flow, wherein embedding the pressure sensitive microparticles comprises:
depositing a photoresist on a silicon substrate;
mold patterning the photoresist to form a predetermined pattern of remaining photoresist on the silicon substrate;
applying a layer of polydimethylsiloxane (PDMS) over the remaining photoresist and the silicon substrate;
removing the PDMS from the remaining photoresist and the silicon substrate leaving a pattern of voids corresponding to the predetermined pattern of remaining photoresist;
preparing a slide having a PDMS layer thereon;
creating pressure sensitive microparticles for measuring fluid flow characteristics on the PDMS layer on the slide; and
positioning the PDMS against the PDMS layer such that the pressure sensitive microparticles are situated within the pattern of voids.

16. A method of measuring pressure fields using a plurality of the pressure sensitive microparticles of claim 1, wherein measuring pressure comprises:
inserting at least one pressure sensitive microparticle into a wall of a channel for fluid flow, said microparticle having a flexible diaphragm which deflects as a function of pressure on the wall;
reflecting a beam of light from the diaphragm of the microparticle, wherein the diaphragm is deflected by pressure from fluid in the fluid flow;
detecting the reflected beam of light;
measuring an output based on a wavelength shift of the reflected beam of light from a pre-reflection wavelength; and
correlating the wavelength shift with a fluid pressure.

17. A method of measuring pressure using the pressure sensitive microparticle of claim 1, wherein measuring pressure comprises:
inserting at least one pressure sensitive microparticle into a fluid flow, said microparticle having a flexible wall which deflects as a function of pressure across the wall;
reflecting a beam of light from the wall of the microparticle, wherein the wall is deflected by pressure from fluid in the fluid flow;
detecting the reflected beam of light;
measuring an output based on a wavelength shift of the reflected beam of light from a pre-reflection wavelength; and
correlating the wavelength shift with a fluid pressure.

18. A method as in claim 17, further comprising detecting fluid flow characteristics based on a plurality of flow positions of the microparticle within the fluid as detected by a detector.

19. A method as in claim 17, further comprising compensating the output for spurious reflections in the fluid from surfaces other than the flexible wall of the microparticle.
